(19) United States
(12) Patent Application Publication
(10) Pub. No.: US 2013/0109200 A1
(43) Pub. Date: May 2, 2013

(54) METHOD FOR MANUFACTURING SEMICONDUCTOR DEVICE

(71) Applicant: Sumitomo Electric Industries, Ltd., Osaka-shi (JP)

(72) Inventor: Tomihito MIYAZAKI, Osaka-shi (JP)

(73) Assignee: Sumitomo Electric Industries, Ltd., Osaka-shi (JP)

(21) Appl. No.: 13/659,494

(22) Filed: Oct. 24, 2012

Related U.S. Application Data
(60) Provisional application No. 61/552,203, filed on Oct. 27, 2011.

(30) Foreign Application Priority Data
Oct. 27, 2011 (JP) 2011-235717

(51) Int. Cl. H01L 21/268

(52) U.S. Cl. 438/787; 257/E21.347

(57) ABSTRACT

There can be obtained a method for manufacturing a semiconductor device in which adherence of particles can be suppressed and printing onto a substrate can be done. The method for manufacturing a semiconductor device includes the steps of: preparing a substrate formed of a semiconductor; forming a protective film to cover at least a part of a main surface of the substrate; and doing printing onto the substrate by irradiating, with laser, the main surface having the protective film. In the step of forming a protective film, the protective film made of a material having a band gap larger than that of the semiconductor constituting the substrate is formed. In the step of doing printing onto the substrate, the substrate is irradiated with laser Lb having such a wavelength that an absorptance of the material for the protective film is smaller than that of the semiconductor constituting the substrate.

### BACKGROUND OF THE INVENTION

1. Field of the Invention

The present invention relates to a method for manufacturing a semiconductor device, and more particularly to a method for manufacturing a semiconductor device in which adherence of particles can be suppressed and printing onto a substrate can be done.

2. Description of the Background Art

In manufacturing a semiconductor device, a step of printing product information such as, for example, a lot number onto a substrate is performed for the purpose of product management and the like. In the step of doing printing onto the substrate, laser marking such as soft marking in which laser irradiation is used to melt a substrate surface to do printing and hard marking in which high-output laser irradiation is used to dig the substrate to do printing is mainly used, for example. Particularly, Japanese Patent Laying-Open No. 2004-39808 describes that the soft marking is a printing method using low-output laser irradiation, and thus, a small amount of particles are only generated due to laser irradiation and the soft marking is used in, for example, printing onto an epitaxial growth surface.

However, even in the case of the soft marking, heat generated due to laser irradiation may cause elements constituting the substrate to leave the substrate (ablation), and these elements may combine with oxygen in the air and form particles. Then, these particles adhere to the substrate surface, which leads to degradation in quality of the semiconductor device manufactured using this substrate.

### SUMMARY OF THE INVENTION

The present invention has been made in light of the aforementioned problem and an object of the present invention is to provide a method for manufacturing a semiconductor device in which adherence of particles can be suppressed and printing onto a substrate can be done.

A method for manufacturing a semiconductor device according to the present invention includes the steps of: preparing a substrate formed of a semiconductor; forming a protective film to cover at least a part of one main surface of the substrate; and doing printing onto the substrate by irradiating, with light, the one main surface covered with the protective film. In the step of forming a protective film, the protective film made of a material having a band gap larger than that of the semiconductor constituting the substrate is formed. In the step of doing printing onto the substrate, the substrate is irradiated with light having such a wavelength that an absorptance of the material for the protective film is smaller than that of the semiconductor constituting the substrate.

In the method for manufacturing a semiconductor device according to the present invention, the protective film made of a material having a band gap larger than that of the semiconductor constituting the substrate is formed, and thereafter, the one main surface having the protective film is irradiated with light having such a wavelength that an absorptance of the material for the protective film is smaller than that of the semiconductor constituting the substrate. In other words, in the method for manufacturing a semiconductor device according to the present invention, printing onto the substrate is done by irradiating the substrate with light reaching the one main surface in the state where the protective film is formed to cover the one main surface. Therefore, generation of particles due to the irradiation with light is suppressed. Thus, in the method for manufacturing a semiconductor device according to the present invention, generation of particles can be suppressed and printing onto the substrate can be done.

In the aforementioned method for manufacturing a semiconductor device, in the step of preparing a substrate, the substrate made of silicon carbide may be prepared. In this case, in the step of doing printing onto the substrate, the substrate may be irradiated with light having a wavelength shorter than 380 nm. Thus, when the substrate made of silicon carbide is used, irradiation with the light having a wavelength shorter than 380 nm allows easy printing onto the substrate.

In the aforementioned method for manufacturing a semiconductor device, in the step of forming a protective film, the protective film made of SiO₂ may be formed. In this case, in the step of doing printing onto the substrate, the substrate may be irradiated with light having a wavelength longer than 140 nm. Thus, by irradiating the substrate with the light having a wavelength longer than 140 nm, a ratio of the light absorbed into the protective film can be reduced and printing onto the substrate can be easily done.

In the aforementioned method for manufacturing a semiconductor device, in the step of forming a protective film, the protective film may be formed by thermal oxidation of the substrate. With this, the protective film that is excellent in adhesiveness can be easily formed.

The aforementioned method for manufacturing a semiconductor device may further include the step of: removing the protective film using BHF or HF. With this, the protective film made of SiO₂ can be easily removed.

In the aforementioned method for manufacturing a semiconductor device, the step of preparing a substrate may include a step of preparing a base substrate and a step of forming an epitaxial growth layer on the base substrate. In the step of forming a protective film, the protective film may be formed on a main surface of the epitaxial growth layer opposite to the base substrate. In other words, in the aforementioned method for manufacturing a semiconductor device, printing may be done onto the epitaxial growth layer constituting the substrate.

As is clear from the above description, in the method for manufacturing a semiconductor device according to the present invention, generation of particles can be suppressed and printing onto the substrate can be done. The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view showing a structure of an MOSFET.

FIG. 2 is a flowchart schematically showing a method for manufacturing the MOSFET.

FIG. 3 is a schematic cross-sectional view for describing the method for manufacturing the MOSFET.

FIG. 4 is a schematic cross-sectional view for describing the method for manufacturing the MOSFET.

FIG. 5 is a schematic cross-sectional view for describing the method for manufacturing the MOSFET.

FIG. 6 is a schematic cross-sectional view for describing the method for manufacturing the MOSFET.

FIG. 7 is a schematic cross-sectional view for describing the method for manufacturing the MOSFET.

FIG. 8 is a schematic cross-sectional view for describing the method for manufacturing the MOSFET.

### DESCRIPTION OF THE PREFERRED EMBODIMENTS

An embodiment of the present invention will be described hereinafter with reference to the drawings, in which the same reference numerals are given to the same or corresponding components and description thereof will not be repeated.

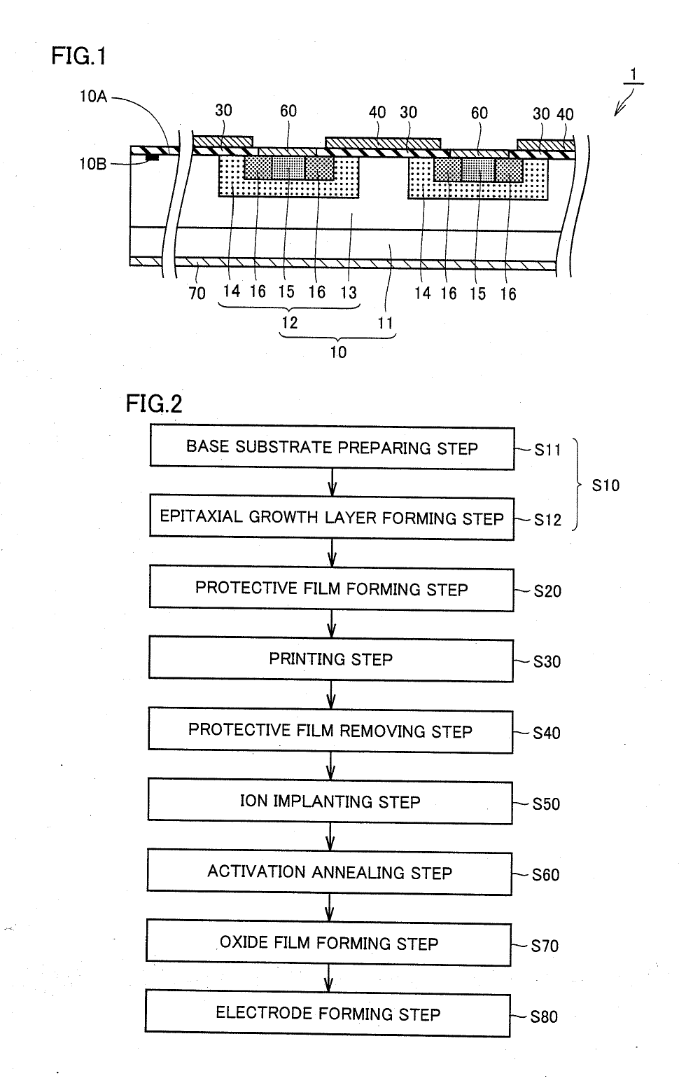

A structure of a semiconductor device according to one embodiment of the present invention will be first described with reference to FIG. 1. An MOSFET 1 serving as the semiconductor device according to the present embodiment includes a substrate 10 made of, for example, silicon carbide and having a main surface 10A, an oxide film 30, a gate electrode 40, a source electrode 60, and a drain electrode 70. Substrate 10 includes a base substrate 11 and a semiconductor layer 12. Semiconductor layer 12 is provided with a drift region 13, a body region 14, a source region 16, and a contact region 15.

Base substrate 11 includes an n-type impurity such as, for example, N (nitrogen), and thus, has n-type conductivity (a first conductivity type). Drift region 13 is formed on one main surface of base substrate 11. Similarly to base substrate 11, drift region 13 includes an n-type impurity such as, for example, N (nitrogen), and thus, has n-type conductivity. A mark 10B is printed onto a region of drift region 13 including main surface 10A. Mark 10B is formed at an outer edge of drift region 13.

Body region 14 includes main surface 10A and is formed on the opposite side of base substrate 11 with respect to drift region 13. Body region 14 includes a p-type impurity such as, for example, Al (aluminum) and B (boron), and thus, has p-type conductivity (a second conductivity type).

Source region 16 includes main surface 10A and is formed in contact with body region 14. Now, source region 16 is described from a different point of view. That is, source region 16 is formed to be surrounded by body region 14 when viewed in a planar view. Similarly to base substrate 11 and drift region 13, source region 16 includes an n-type impurity such as, for example, P (phosphorus), and thus, has n-type conductivity.

Contact region 15 includes main surface 10A and is formed in contact with source region 16. Now, contact region 15 is described from a different point of view. That is, contact region 15 is formed to be surrounded by source region 16 when viewed in a planar view. Similarly to body region 14, contact region 15 includes a p-type impurity such as, for example, Al (aluminum) and B (boron), and thus, has p-type conductivity.

Oxide film 30 is formed to partially cover main surface 10A. Oxide film 30 is made of, for example, SiO₂ (silicon dioxide).

Gate electrode 40 is formed in contact with oxide film 30. Gate electrode 40 is formed of, for example, an impurity-doped conductor made of polysilicon, Al (aluminum) and the like. Gate electrode 40 is formed to extend from one source region 16 to the other source region 16 that face each other under gate electrode 40.

Source electrode 60 is formed in contact with source region 16 and contact region 15. Source electrode 60 is made of a material that can come into ohmic contact with source region 16, such as, for example, NiₓSi_{y} (nickel silicide), TiₓSi_{y} (titanium silicide), AlₓSi_{y} (aluminum silicide), and TiₓAl_{y}Si_{z} (titanium aluminum silicide). Source electrode 60 is electrically connected to source region 16.

Drain electrode 70 is formed on the main surface of base substrate 11 opposite to drift region 13. Drain electrode 70 is made of a material that can come into ohmic contact with base substrate 11, such as, for example, a material similar to that of source electrode 60.

Next, the operation of MOSFET 1 serving as the semiconductor device according to the present embodiment will be described. Referring to FIG. 1, even if a voltage is applied to between source electrode 60 and drain electrode 70 in a state where a voltage applied to gate electrode 40 is less than a threshold voltage, i.e., in an OFF state, p-n junction formed between body region 14 and drift region 13 is reverse biased and conduction does not occur. On the other hand, when a voltage equal to or larger than the threshold voltage is applied to gate electrode 40, an inversion layer is formed in a channel region (body region 14 under gate electrode 40) in body region 14. As a result, source region 16 is electrically connected to drift region 13 and a current flows between source electrode 60 and drain electrode 70. MOSFET 1 operates as described above.

Next, a method for manufacturing the semiconductor device according to the present embodiment will be described. In the method for manufacturing the semiconductor device according to the present embodiment, aforementioned MOSFET 1 serving as the semiconductor device according to the present embodiment is manufactured. Referring to FIG. 2, a substrate preparing step is first performed as step (S10). In this step (S10), steps (S11) and (S12) described below are performed, and thereby substrate 10 made of silicon carbide is prepared.

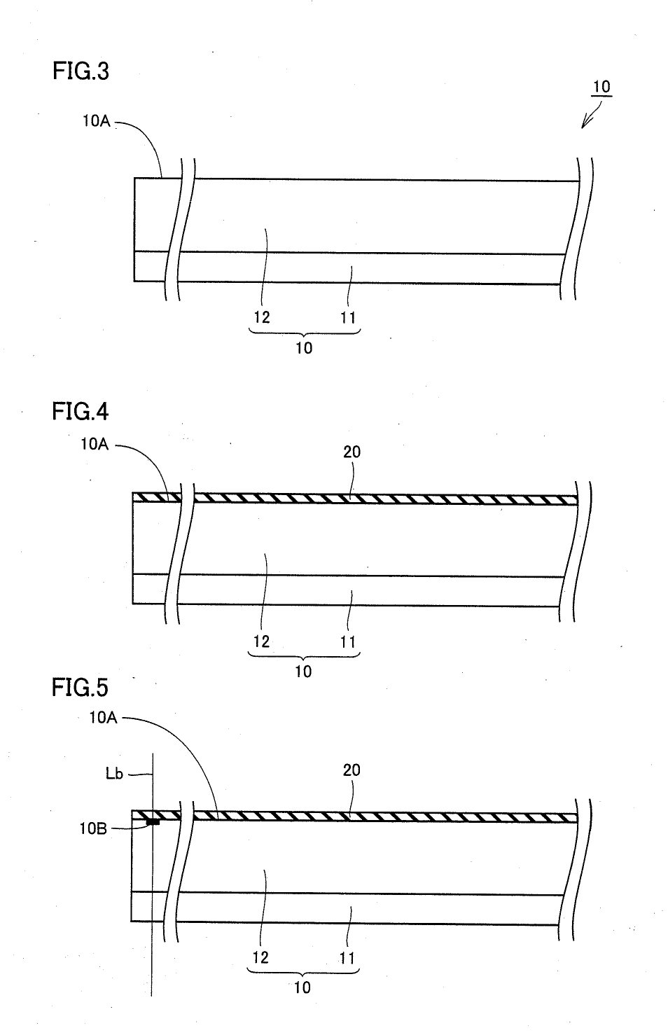

A base substrate preparing step is first performed as step (S11). In this step (S11), referring to FIG. 3, an ingot made of, for example, 4H—SiC is sliced, and thereby base substrate 11 made of silicon carbide is prepared. Next, an epitaxial growth layer forming step is performed as step (S12). In this step (S12), semiconductor layer 12 is formed on one main surface of base substrate 11 by epitaxial growth.

Although substrate 10 made of silicon carbide may be prepared in this step (S10) as described above, the present invention is not limited thereto. A substrate formed of a semiconductor selected from the group consisting of, for example, GaN, AIN, GaAs, InP, and Si may be prepared.

Next, a protective film forming step is performed as step (S20). In this step (S20), a protective film is formed to cover at least a part of main surface 10A of substrate 10. More specifically, referring to FIG. 4, by thermal oxidation of substrate 10 in an atmosphere containing, for example, oxygen, a protective film 20 made of SiO₂ (silicon dioxide) is formed on a region including main surface 10A of substrate 10. As described above, thermal oxidation is selected as a method for forming protective film 20, and thus, the protective film that is excellent in adhesiveness can be easily formed.

In this step (S20), protective film 20 made of a material having a band gap larger than that of the semiconductor constituting substrate 10 may only be formed, and protective film 20 made of, for example, SiN (silicon nitride) and Al₂O₃ (aluminum oxide) may be formed. It is to be noted that protective film 20 made of SiN (silicon nitride) has a different light absorption property due to a method for forming protective film 20. Therefore, when SiN (silicon nitride) is used as a material for protective film 20, protective film 20 is formed in consideration of the foregoing.

Although protective film 20 may be formed by thermal oxidation of substrate 10 in this step (S20), the present invention is not limited thereto. Protective film 20 may be formed using, for example, a CVD (Chemical Vapor Deposition) method, an SOG (Spin On Glass) application method, a sputtering method, a vacuum vapor deposition method and the like. Even when substrate 10 is formed of the semiconductor selected from the group consisting of GaN, AIN, GaAs, InP, and Si, protective film 20 can be made of SiO₂ (silicon dioxide).

Next, a printing step is performed as step (S30). In this step (S30), referring to FIG. 5, main surface 10A of substrate 10 covered with protective film 20 is irradiated with laser Lb, and thereby mark 10B is printed onto substrate 10. More specifically, main surface 10A of substrate 10 is irradiated with laser Lb having a wavelength longer than 140 nm and shorter than 380 nm, which is laser Lb having such a wavelength that an absorptance of the material for protective film 20 is smaller than that of the semiconductor constituting substrate 10, i.e., laser having such a wavelength that an absorptance of silicon dioxide is smaller than that of silicon carbide in the present embodiment. Then, irradiated laser Lb passes through protective film 20 and reaches main surface 10A of substrate 10. As a result, mark 10B is formed on a region including main surface 10A. In this step (S30), ArF excimer laser, KrF excimer laser, YAG (Yttrium Aluminium Garnet) third harmonic (wavelength: 355 nm), YAG fourth harmonic (wavelength: 266 nm) or the like can, for example, be used as laser Lb. Mark 10B may be a lot number, an alignment mark, a mark for identifying each chip, or the like.

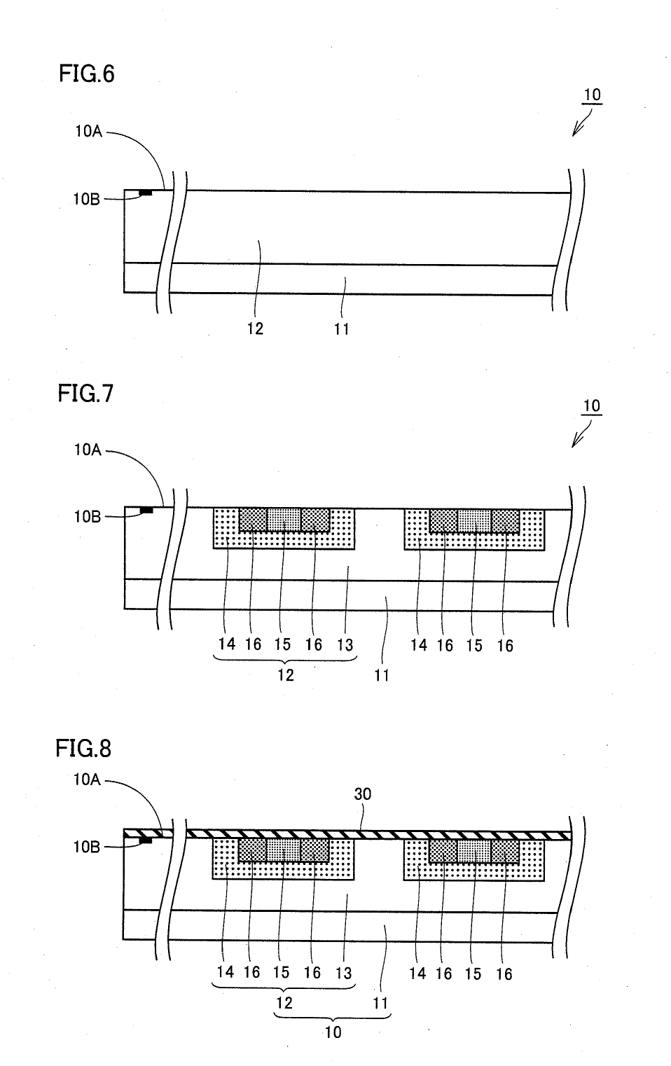

Next, a protective film removing step is performed as step (S40). In this step (S40), referring to FIG. 6, substrate 10 is treated using, for example, BHF (buffered hydrofluoric acid), HF (hydrofluoric acid) or the like, and thereby protective film 20 is removed. This step (S40) is not essential in the method for manufacturing the semiconductor device according to the present invention. However, by performing this step, protective film 20 that is unnecessary for the operation of MOSFET 1 can be removed. This step (S40) may be performed after step (S50) described later.

Next, an ion implanting step is performed as step (S50). In this step (S50), referring to FIG. 7, Al ions are, for example, implanted into a region including main surface 10A, and thereby body region 14 including main surface 10A is formed. Next, P ions are, for example, implanted into the region including main surface 10A at an implantation depth shallower than an implantation depth of the aforementioned Al ions, and thereby source region 16 is formed. Then, Al ions are, for example, implanted into the region including main surface 10A at an implantation depth that is nearly equal to the implantation depth of the aforementioned P ions, and thereby contact region 15 is formed. In the aforementioned step (S50), a region of semiconductor layer 12 where body region 14, source region 16 and contact region 15 are not formed configures drift region 13.

Next, an activation annealing step is performed as step (S60). In this step (S60), substrate 10 is heated, and thereby the impurities introduced in the aforementioned step (S50) are activated. As a result, desired carriers are generated in the regions where the impurities have been introduced.

Next, an oxide film forming step is performed as step (S70). In this step (S70), referring to FIG. 8, substrate 10 is heated in an atmosphere containing, for example, oxygen, and thereby oxide film 30 made of SiO₂ (silicon dioxide) is formed to cover main surface 10A.

Next, an electrode forming step is performed as step (S80). In this step (S80), referring to FIG. 1, gate electrode 40 made of polysilicon is first formed on oxide film 30 using, for example, an LPCVD (Low Pressure Chemical Vapor Deposition) method.

Next, oxide film 30 in a region where source electrode 60 should be formed is removed, and thereby a region having exposed source region 16 and exposed contact region 15 is formed. Then, a film made of, for example, Ni is formed on the region. On the other hand, a film made of, for example, Ni is formed on the main surface of base substrate 11 opposite to the side where drift region 13 is formed. Thereafter, alloying thermal treatment is performed and at least a part of the films made of Ni is silicided. As a result, source electrode 60 and drain electrode 70 are formed. By performing the aforementioned steps (S10) to (S80), MOSFET 1 serving as the semiconductor device according to the present embodiment is manufactured and the method for manufacturing the semiconductor device according to the present embodiment is completed.

As described above, in the method for manufacturing the semiconductor device according to the present embodiment, protective film 20 made of a material having a band gap larger than that of the semiconductor constituting substrate 10 is formed, and thereafter, main surface 10A having protective film 20 is irradiated with laser Lb having such a wavelength that an absorptance of the material for protective film 20 is smaller than that of the semiconductor constituting substrate 10. In other words, in the method for manufacturing the semiconductor device according to the present embodiment, mark 10B is printed onto substrate 10 by irradiating the substrate with laser Lb reaching main surface 10A in the state where protective film 20 is formed to cover main surface 10A. Therefore, generation of particles due to the irradiation with laser Lb is suppressed. Thus, in the method for manufacturing the semiconductor device according to the present embodiment, generation of particles can be suppressed and mark 10B can be printed onto substrate 10.

Although the method for manufacturing the planar (flat plate) type MOSFET has been described in the present embodiment, the method for manufacturing the semiconductor device according to the present invention is not limited thereto. The aforementioned method for manufacturing the semiconductor device according to the present invention may be applied to manufacturing of other semiconductor devices such as, for example, a trench (groove) type MOSFET and an IGBT (Insulated Gate Bipolar Transistor).

The method for manufacturing the semiconductor device according to the present invention can be particularly advantageously applied to a method for manufacturing a semiconductor device that requires suppression of generation of particles and printing onto a substrate.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a semiconductor device, comprising the steps of:
preparing a substrate formed of a semiconductor;
forming a protective film to cover at least a part of one main surface of said substrate; and
doing printing onto said substrate by irradiating, with light, said one main surface covered with said protective film, wherein
in said step of forming a protective film, said protective film made of a material having a band gap larger than that of the semiconductor constituting said substrate is formed, and
in said step of doing printing onto said substrate, said substrate is irradiated with light having such a wavelength that an absorptance of the material for said protective film is smaller than that of the semiconductor constituting said substrate.

2. The method for manufacturing a semiconductor device according to claim 1, wherein
in said step of preparing a substrate, said substrate made of silicon carbide is prepared, and
in said step of doing printing onto said substrate, said substrate is irradiated with light having a wavelength shorter than 380 nm.

3. The method for manufacturing a semiconductor device according to claim 2, wherein
in said step of forming a protective film, said protective film made of SiO₂ is formed, and
in said step of doing printing onto said substrate, said substrate is irradiated with light having a wavelength longer than 140 nm.

4. The method for manufacturing a semiconductor device according to claim 3, wherein
in said step of forming a protective film, said protective film is formed by thermal oxidation of said substrate.

5. The method for manufacturing a semiconductor device according to claim 3, further comprising the step of:
removing said protective film using BHF or HF.

6. The method for manufacturing a semiconductor device according to claim 1, wherein
said step of preparing a substrate includes a step of preparing a base substrate and a step of forming an epitaxial growth layer on said base substrate, and
in said step of forming a protective film, said protective film is formed on a main surface of said epitaxial growth layer opposite to said base substrate.
